(19) United States
(12) Patent Application Publication
(10) Pub. No.: US 2026/0196973 A1
(43) Pub. Date: Jul. 9, 2026

(54) GENERATING DIGITAL PREDISTORTION MODELS USING PERFORMANCE METRICS

(71) Applicant: Telefonaktiebolaget LM Ericsson (publ), Stockholm (SE)

(72) Inventors: Hao GAO, Chaoyang District, Beijing (CN); Mohan YANG, Beijing (CN); Viacheslav PRIMENKO, Stockholm (SE); Liushuan ZHOU, Chaoyang District, Beijing (CN); Peng LIU, Chaoyang District, Beijing (CN)

(73) Assignee: Telefonaktiebolaget LM Ericsson (publ), Stockholm (SE)

(21) Appl. No.: 19/134,262

(22) PCT Filed: Dec. 1, 2022
(86) PCT No.: PCT/CN2022/135936

§ 371 Date: May 30, 2025

(51) Int. Cl. H03F 1/32; G06F 11/34; G06F 11/3668

(52) U.S. Cl. CPC H03F 1/3247; G06F 11/3447; G06F 11/3684

(57) ABSTRACT

A method for determining a plurality of digital pre-distortion, DPD, models. The method comprising obtaining test data indicating a set of test cases. The method further comprising dividing the set of test cases into subsets of test cases. The method further comprising determining a DPD model for each subset of test cases, thereby determining the plurality of DPD models.

### TECHNICAL FIELD

This disclosure relates to generating digital predistortion models using performance metrics.

### BACKGROUND

Wireless communication networks use linearization to compensate for the nonlinearity of radio frequency (RF) circuits. Typically, the spectrum regrowth of a power amplifier within the RF circuit is a source of such nonlinearity. Digital predistortion (DPD) is a common method for mitigating the nonlinearity of power amplifiers. Due to the potential advantages over other nonlinearity correction methods in terms of reducing size and cost, DPD has become an indispensable technology for RF circuits.

The effects of the memory which corresponds to memory taps such as data and address taps in both power amplifier modeling and DPD modeling are unavoidable in the realistic systems because the output of a power amplifier does not only depend on the current stage of the input, but also depends on the previous input of the power amplifier.

DPD models commonly use several base functions to characterize the relationship between the input and the output of the DPD. In general, DPD performance increases with more base functions at the expense of computational complexity and resource utilization. As such, DPD model optimization, or limiting the number of DPD models, is required as products have limited memory taps. Optimization strategies can be generally classified as the priori strategies and the posterior strategies. The priori optimization strategies are applied without knowledge of the internal structure of the power amplifier, while several posterior strategies use the signal processing techniques based on the sparsity assumption for the DPD model optimization.

Some search strategies used in DPD model optimization involve sweeping an interested area in a parameter space. Some of these strategies involve trial and error, increasing the number of parameters and searching all the parameter combinations. For example a tap searching tool uses search techniques to optimize DPD parameters to achieve desired performance and stability of radio products, which can store a database with different settings for different test cases.

### SUMMARY

Certain challenges exist. Generally, multiple DPD models need to be optimized for different test cases in order to meet DPD performance requirements. For example, test cases with parameters (e.g., instantaneous bandwidth (IBW), occupied bandwidth (OBW) or frequency position) having substantially different values are likely to result in different optimized DPD models. Since radio products may have hundreds of test cases, it is unreasonable to provide an individual DPD model for each test case, for example, due to the high memory cost.

Thus, in practice, only a reasonably small number of optimized DPD models is optimized for the test cases. For example, for some troublesome test cases, several specialized DPD models are optimized. But optimizing such DPD models may require manually selecting specific test cases from those troublesome test cases.

For example, in case a test is run and the result of the test has distributed failed cases, in some optimization processes, a failed test case is manually selected to re-run model parameter optimization. However, manually selecting a test case may not lead to good coverage for the failed test cases. For example, in case the selected test case is a not representative failed test case but is deviated from the rest of the failed test cases, if a DPD model is optimized for the selected test case, such DPD model will not perform well with respect to the rest of the failed test cases. Thus, this manual decision-making process can be treated as trial-and-error.

Even with the experience of experts, it is difficult to optimize the analysis and automate the implementation. This process may require a large amount of man hours to finish the model parameter optimization for all test cases for a single product. For example, it may take around two weeks to find a suitable result of DPD model parameters for one product.

K-Means clustering can be used for clustering test cases and a DPD model can be optimized for each cluster of test cases. However, clustering optimization is typically defined in the feature state space, which cannot directly make the connection with the final performance. Therefore, the clustering result and the prediction results cannot guarantee satisfying performance requirements, thereby limiting the application of the K-Means clustering to real products.

Accordingly, in some embodiments, there is provided an efficient DPD optimization process. In the efficient DPD optimization process according to some embodiments, DPD model clustering optimization can be reformulated to make a direct connection with the final performance by embedding the DPD models with a measured performance projection.

More specifically, in one aspect of the embodiments of this disclosure, there is provided a method for determining a plurality of digital predistortion, DPD, models. The method comprises obtaining test data indicating a set of test cases. The method further comprises dividing the set of test cases into subsets of test cases. The method further comprises determining a DPD model for each subset of test cases, thereby determining the plurality of DPD models.

In another aspect, there is provided a method for generating output data using a plurality of digital predistortion, DPD, models. The method comprises obtaining input data. The method further comprises obtaining performance metric, PM, values wherein each PM value included in the PM values indicates performance measurement of the input data, which is obtained using one of the plurality of DPD models. The method further comprises, based on the obtained PM values, selecting from the plurality of DPD models a DPD model to use for the input data. The method further comprises providing the input data to the selected DPD model, thereby generating the output data.

In another aspect, there is provided a computer program comprising instructions which when executed by processing circuitry cause the processing circuitry to perform the method of any one of the embodiments described above.

In another aspect, there is provided an apparatus for determining a plurality of digital predistortion, DPD, models. The apparatus is configured to obtain test data indicating a set of test cases. The apparatus is further configured to divide the set of test cases into subsets of test cases. The apparatus is further configured to determine a DPD model for each subset of test cases, thereby determining the plurality of DPD models.

In another aspect, there is provided an apparatus for generating output data using a plurality of digital predistortion, DPD, models. The apparatus is configured to obtain input data. The apparatus is further configured to obtain performance metric, PM, values wherein each PM value included in the PM values indicates performance measurement of the input data, which is obtained using one of the plurality of DPD models. The apparatus is further configured to, based on the obtained PM values, select from the plurality of DPD models a DPD model to use for the input data. The apparatus is further configured to provide the input data to the selected DPD model, thereby generating the output data.

In other aspect, there is provided an apparatus. The apparatus comprises a processing circuitry and a memory, said memory containing instructions executable by said processing circuitry, whereby the apparatus is operative to perform the method of any one of the embodiments described above.

The embodiments described herein provide DPD model parameter optimization for all test cases in an efficient manner without an excessive amount of trial and error. The embodiments automate the DPD model optimization process reducing man hours and the number of DPD models required. The DPD performance in the embodiments are in tune with the performance space. The embodiments described herein customize the optimization target based on the performance. Additionally, the embodiments described herein provide a solution for DPD online tuning with limited computational complexity, reduce power consumption by using cheap DPD models while meeting the performance requirements, and reduce design cost and shorten time-to-market.

### BRIEF DESCRIPTION OF THE DRAWINGS

The accompanying drawings, which are incorporated herein and form part of the specification, illustrate various embodiments.

FIG. 1 shows a portion of a wireless network system according to some embodiments.

FIG. 2 shows a functional/block diagram for a signal transmission circuit according to some embodiments.

FIGS. 3A and 3B illustrate different methods of generating DPD models.

FIG. 4 shows a process for generating DPD models for clusters of test cases.

FIG. 5 shows a graph comparing the normalized mean squared error (NMSE) performance of two optimization methods.

FIG. 6 shows a graph comparing the NMSE performance of two optimization methods.

FIG. 7 shows a functional/block diagram for a signal transmission circuit according to some embodiments.

FIG. 8 shows a process according to some embodiments.

FIG. 9 shows a process according to some embodiments.

FIG. 10 shows an apparatus according to some embodiments.

### DETAILED DESCRIPTION

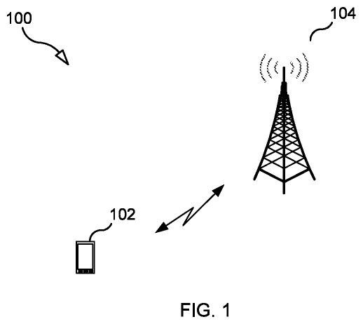

FIG. 1 shows a portion of a wireless network system 100 according to some embodiments. Wireless network system 100 comprises a user equipment (UE) 102 and a base station 104. UE 102 may be configured to transmit signal(s) towards base station 104, and base station 104 may be configured to receive the signal(s) transmitted by UE 102. Additionally or alternatively, base station 104 may be configured to transmit signal(s) towards UE 102, and UE 102 may be configured to receive the signal(s) transmitted by base station 104. The number of UE(s) and the number of base station(s) shown in FIG. 1 are provided for simple explanation purpose only and do not limit the embodiments of this disclosure in any way.

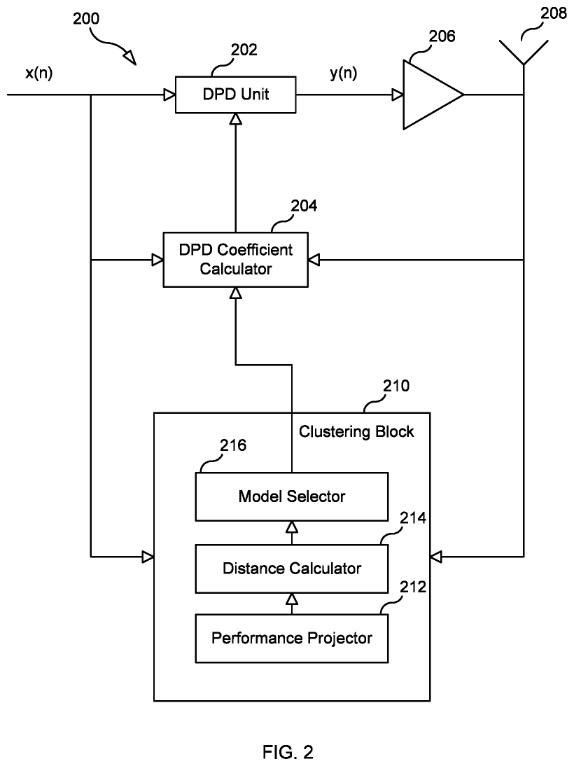

In transmitting the signals towards UE 102, base station 104 may use a signal transmission (Tx) circuit. FIG. 2 shows a portion of Tx circuit 200 according to some embodiments. Circuit 200 may be located within base station 104, and may include a DPD unit 202, a DPD coefficient calculator 204, a power amplifier 206, and an antenna 208. When base station 104 transmits a signal towards UE 102 using antenna 208, base station 104 may first amplify the signal with power amplifier 206. In an alternative embodiment, circuit 200 may be located within UE 102.

However, as discussed above, during the amplification, power amplifier 206 may cause nonlinearity and distort the signal. Circuit 200 compensates for the nonlinearity of power amplifier 206 with DPD unit 202 and DPD coefficient calculator 204. DPD coefficient calculator 204 may receive an input data x(n) and the output of power amplifier 206. Upon receiving the input data and the output of power amplifier 206, DPD coefficient calculator 204 may calculate DPD coefficients based on the received input data and the output of power amplifier 206, and transmit the calculated DPD coefficients to DPD unit 202. Then DPD unit 202 may use the DPD coefficients to perform DPD operation, thereby generating and outputting a modified data y(n) to power amplifier 206.

In some embodiments, circuit 200 may include a plurality of DPD models. In some embodiments, the DPD models may be embodied as memory polynomial (MP) or look-up table (LUT) based models. Both of these models use several base functions to characterize the relationship between the input and the output of DPD. The MP and LUT based models can be expressed as equations (1) and (2), respectively.

$$y ( n ) = {\sum }_{m , l , k} {a}_{m , l , k} x ( n - m ) \cdot {\vert x ( n - l ) \vert}^{k} \qquad ( 1 )$$

$$y ( n ) = {\sum }_{m , l} x ( n - m ) \cdot {f}_{m , l} ( \vert x ( n - l ) \vert ) \qquad ( 2 )$$

where x(n) and y(n) are the model input and model output, respectively. n is the discrete time index, n=0, 1, 2, . . . , N−1. m and l are the memory taps, also known as the data delay and the address delay, respectively. k in equation (1) is the nonlinear order, and a_{m,l,k} is the model coefficient. f_{m,l} in equation (2) denotes the LUT values corresponding to the data delay m and the address delay 1.

In other embodiments, the DPD models may be embodied as polynomial based, Volterra series based, or neural network based models. There can be different model parameters in different DPD models. For example, a general memory polynomial model also includes the parameter of nonlinearity order. Without loss of generality, the embodiments described herein can use any DPD model.

The DPD models included in circuit 200 may be optimized with performance projections. More specifically, according to some embodiments, circuit 200 may include a clustering block 210 that is configured to provide an optimized DPD model to DPD coefficient calculator 204. Clustering block 210 may include a performance projector 212, a distance calculator 214, and a model selector 216.

In some embodiments, when circuit 200 receives input data x(n), clustering block 210 receives the input data x(n) along with DPD unit 202 and DPD coefficient calculator 204. Performance projector 212 may then obtain performance metrics values indicating performance measurements of the input data x(n) using a plurality of DPD models located within clustering block 210. The table provided below illustrates a simplified example of performance metric values obtained by performance projector 212.

| | | |
|---|---|---|
| Input Data x(n) | DPD Model #1 | Performance Measurement Matrix #1 |
| Input Data x(n) | DPD Model #2 | Performance Measurement Matrix #2 |
| Input Data x(n) | DPD Model #3 | Performance Measurement Matrix #3 |
| Input Data x(n) | DPD Model #4 | Performance Measurement Matrix #4 |
| Input Data x(n) | DPD Model #5 | Performance Measurement Matrix #5 |

As shown above, in case there are five DPD models #1-#5 in clustering block 210, performance projector 212 may generate five performance measurement matrices #1-#5 using the five DPD models #1-#5. For example, performance projector 212 may generate performance measurement matrix #1 using DPD model #1 and performance measurement matrix #2 using DPD model #2. Each performance measurement matrix is a set of performance measurement values obtained using a certain DPD model.

Distance calculator 214 may then convert the performance metrics values into distance values. In some embodiments, distance calculator 214 may convert the performance metrics values into distance values using weight factors

$$d ( \vec{p} ) = [ {w}_{1} , {w}_{2} , … {w}_{M} ] \cdot {[ {p}_{1} , {p}_{2} , … {p}_{M} ]}^{T} \qquad ( 3 )$$

where p₁, p₂, . . . p_{M} are the performance metrics and w₁, w₂, . . . w_{M} are the weights of different performance metrics. The resulting d(\vec{p}) distance value is equal to summation of w₁.p₁+w₂p₂+ . . . wₘ.pₘ.

Distance calculator 214 may then compare the distance values and identify a smallest distance value among the compared distance values. Model selector 216 may then select from among the plurality of DPD models the DPD model associated with the smallest distance value. Clustering block 210 may then output the selected DPD model (i.e., the DPD model with the smallest distance value) to DPD coefficient calculator 204. DPD coefficient calculator 204 may calculate DPD coefficients using the selected DPD model, and provide the calculated DPD coefficients to DPD unit 202, which may then use the DPD coefficients to generate output data y(n) to power amplifier 206.

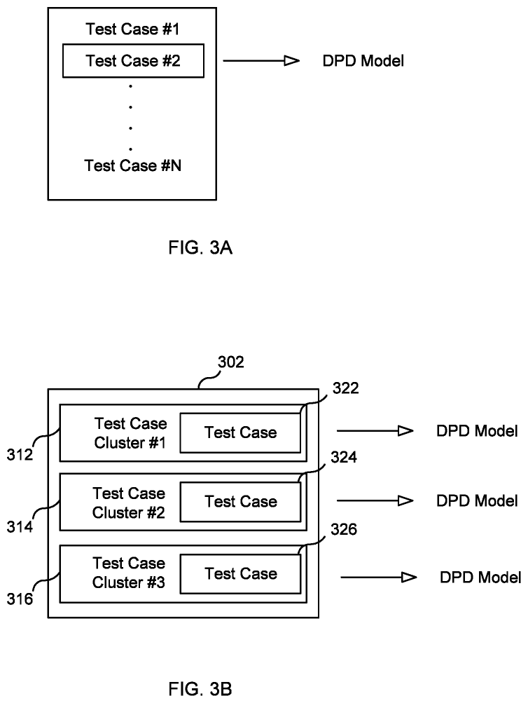

The DPD models stored in clustering block 210 may be generated using a plurality of test cases. FIGS. 3A and 3B illustrate how the DPD models are generated using the test cases.

As shown in FIG. 3A, a test case (e.g., Test Case #2) may be randomly selected, and a DPD model optimized for the randomly selected test case may be generated. However, there may be a scenario where this randomly selected test case is very different from other test cases, and thus the DPD model optimized for the randomly selected test case may not be optimal for the other test cases.

In order to solve such problem, according to some embodiments, from among the plurality of test cases, one or more representative test cases are identified, and DPD models optimized for the representative test cases are generated. For example, in FIG. 3B, a test case set 302 comprises three clusters 312, 314, 316 of test cases. Each cluster of test cases includes at least one representative test case. First cluster 312 of test cases includes a representative test case 322, second cluster 314 of test cases includes a representative test case 324, and a third cluster 316 of test cases includes a representative test case 326.

According to some embodiments, a DPD model optimized for each representative test case 322, 324, or 326 is generated. In some embodiments, the one or more representative test cases may be identified based on real world performance measurements. Note that even though FIG. 3B shows that there are three representative test cases, the number of representative test cases and the number of clusters of test cases can be any number.

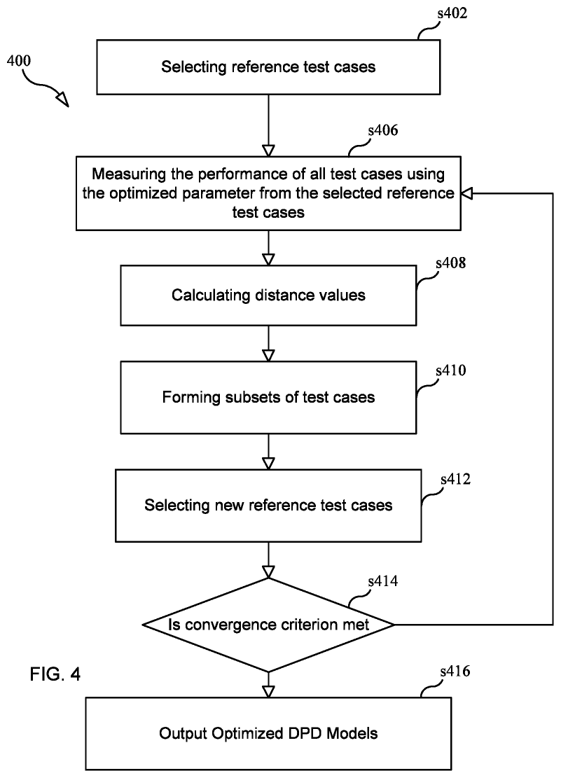

As discussed above, a DPD model to use for processing (e.g., by DPD unit 202) the input data (e.g., x(n) shown in FIG. 2) may be selected from DPD models corresponding to clusters of test cases. FIG. 4 shows a process 400 for determining the DPD models corresponding to the clusters of test cases, according to some embodiments. More specifically, process 400 is for determining clusters of test cases, determining a reference test case for each cluster of test cases, and generating a DPD model for each reference test case, thereby generating the DPD models corresponding to the clusters of test cases.

The process 400 begins with step s402. In step s402, the process 400 selects reference test cases from a plurality of test cases. The reference test cases may be selected randomly or based on some evaluation and/or algorithm. In some embodiments, the number of the selected reference test cases may be K, which is applied in the conventional K-Means algorithm. In other embodiments, however, any number of reference test cases may be selected.

Each test case may be defined by a number of parameters. The number of the parameters can be any number greater than or equal to 1. For example, a test case may be defined by the following three parameters: instantaneous bandwidth (IBW), occupied bandwidth (OBW), weighted mean frequency (WMF), where WMF is defined by equation (4).

$$WMF = \frac{{\sum }_{1}^{n} {f}_{n} \cdot {BW}_{n}}{{\sum }_{1}^{n} {BW}_{n}} \qquad ( 4 )$$

where fₙ and BWₙ denote the n-th carrier frequency and bandwidth, respectively. In such embodiments, the test case c(i, o, w) is defined in the three-dimensional test case parameter space, where i, o, and w represent the dimension IBW, OBW and WMF, respectively.

The test cases may be generated based on the experience from experts or a random distribution. In some embodiments, there are in total N discrete test cases sampled from the whole parameter space, which make up a test case set:

$$C = \{ {c}_{n} , n = 1 , 2 , 3 , … N \} \qquad ( 5 )$$

where cₙ represents the n-th test case.

After performing step s402, the process 400 may proceed to step s406. In step s406, the performance is measured for all test cases using the optimized parameters from each reference test case. The performance projection may be defined as

$$p ( {c}_{n} , {r}_{k} ) = \vec{p} = {[ {p}_{1} , {p}_{2} , … {p}_{M} ]}^{T} \qquad ( 6 )$$

where the performance p(cₙ, rₖ) is measured on test case cₙ, using the optimized DPD model parameters (i.e., data delay and address delay taps) from reference test case rₖ.

To obtain the performance measurements, in some embodiments, process 400 first obtains an optimized data delay m and address delay l from each reference test case rₖ. Then process 400 builds a DPD model associated with m and l by substituting m and l into the DPD model of cₙ, i.e., equations (1) and (2). Equations (1) and (2) are presented again below.

$$y ( n ) = {\sum }_{m , l , k} {a}_{m , l , k} x ( n - m ) \cdot {\vert x ( n - l ) \vert}^{k} \qquad ( 1 )$$

$$y ( n ) = {\sum }_{m , l} x ( n - m ) \cdot {f}_{m , l} ( \vert x ( n - l ) \vert ) \qquad ( 2 )$$

where x(n) is the model input and y(n) is the model output. n is the discrete time index, n=0, 1, 2, . . . , N−1. m and l are the optimized data delay m and address delay l from each reference test case. k in equation (1) is the nonlinear order, and a_{m,l,k} is the model coefficient. f_{m,l} in equation (2) denotes the LUT values corresponding to the data delay m and the address delay 1.

After building the DPD model, x(n) is transmitted through the DPD model and the power amplifier. Finally, the performance measurements or metrics may be obtained using the output of the power amplifier. In some embodiments, an instrument (e.g., spectrum analyzer) can indicate the ACLR (adjacent channel leakage ratio) performance by measuring the output signal of power amplifier. In other embodiments, a calculation block may obtain a NMSE (normalized mean squared error) value by comparing the output signal of the power amplifier and x(n).

The performance metrics may be embodied as a performance vector [p₁, p₂, . . . p_{M}]^{T} which includes M performance metrics. In some embodiments, the performance metrics may include, for example, OBUE (operating band unwanted emissions) margin, ACLR, and NMSE. NMSE may be defined as:

$$NMSE = 10 {log}_{10} \frac{{\sum }_{n = 1}^{N} {\vert d ( n ) - z ( n ) \vert}^{2}}{{\sum }_{n = 1}^{N} {\vert d ( n ) \vert}^{2}} \qquad ( 7 )$$

where d(n) and z(n) are the desired signal and the measured signal, respectively.

Table 1 provides an illustrative example of the results of step s406. In particular, each test case will have a set of performance metrics (i.e., a performance vector) corresponding to each reference test case.

TABLE 1
Sample Performance Metrics For Test Cases

| | | |
|---|---|---|
| Test Case #1 | Reference Test Case #1 | p(c₁, r₁) = [p₁, p₂, . . . p_{M}]^{T} |
| | Reference Test Case #2 | p(c₁, r₂) = [p₁, p₂, . . . p_{M}]^{T} |
| | Reference Test Case #3 | p(c₁, r₃) = [p₁, p₂, . . . p_{M}]^{T} |
| Test Case #2 | Reference Test Case #1 | p(c₂, r₁) = [p₁, p₂, . . . p_{M}]^{T} |
| | Reference Test Case #2 | p(c₂, r₂) = [p₁, p₂, . . . p_{M}]^{T} |
| | Reference Test Case #3 | p(c₂, r₃) = [p₁, p₂, . . . p_{M}]^{T} |
| . . . | . . . | . . . |
| Test Case #N | Reference Test Case #1 | p(c_{N}, r₁) = [p₁, p₂, . . . p_{M}]^{T} |
| | Reference Test Case #2 | p(c_{N}, r₂) = [p₁, p₂, . . . p_{M}]^{T} |
| | Reference Test Case #3 | p(c_{N}, r₃) = [p₁, p₂, . . . p_{M}]^{T} |

Using the performance projection, the test case parameter space has been projected onto a DPD performance space. In the traditional K-Means algorithm, there is no performance projection which means that the parameter space cannot directly connect with the final performance. In some embodiments, projecting test cases onto the DPD performance space necessitates physical test measurements.

Referring back to FIG. 4, in step s408, process 400 calculates distance values for each of the test cases. In some embodiments, the distance calculation may be defined as:

$$d ( {c}_{n} , {r}_{k} ) = d ( p ( {c}_{n} , {r}_{k} ) ) = d ( \vec{p} ) \qquad ( 8 )$$

which denotes the distance from the test case cₙ to the reference test case rₖ. Here it is also noted that if the distance is directed from the test case A to test case B or d(A, B), test case B is regarded as the reference case. In some embodiments, d can be a linear function as follows

$$d ( \vec{p} ) = [ {w}_{1} , {w}_{2} , … {w}_{M} ] \cdot {[ {p}_{1} , {p}_{2} , … {p}_{M} ]}^{T} \qquad ( 3 )$$

where w₁, w₂, . . . w_{M} are the weights of different performance metrics. The resulting d(p) is a distance value.

Table 2 provides an illustrative example of the results of step s408. In particular, each test case will have a distance value corresponding to each reference test case.

TABLE 2
Sample Distance Value For Test Cases

| | | |
|---|---|---|
| Test Case #1 | Reference Test Case #1 | d(c₁, r₁) |
| | Reference Test Case #2 | d(c₁, r₂) |
| | Reference Test Case #3 | d(c₁, r₃) |
| Test Case #2 | Reference Test Case #1 | d(c₂, r₁) |
| | Reference Test Case #2 | d(c₂, r₂) |
| | Reference Test Case #3 | d(c₂, r₃) |
| . . . | . . . | . . . |
| Test Case #N | Reference Test Case #1 | d(c_{N}, r₁) |
| | Reference Test Case #2 | d(c_{N}, r₂) |
| | Reference Test Case #3 | d(c_{N}, r₃) |

In some embodiments, defined distance is different from the Euclidean distance in the traditional K-Means, which doesn't satisfy the symmetry property that the distance from cᵢ to cⱼ is the same as the distance from cⱼ to cᵢ, i.e., if i≠j, in the present embodiment,

$$d ( {c}_{i} , {c}_{j} ) \neq d ( {c}_{j} , {c}_{i} ) \qquad ( 9 )$$

In some embodiments, the corresponding distance d(cₙ, rₖ) between all test cases cₙ and all the reference cases rₖ are calculated based on the distance function definition in equation(8). The distance values can be represented as a distance matrix D∈ [symbol] ^{N×K}:

$$D = [ \begin{matrix}d ( {c}_{1} , {r}_{1} ) & ⋯ & d ( {c}_{1} , {r}_{K} ) \\ ⋮ & ⋱ & ⋮ \\ d ( {c}_{N} , {r}_{1} ) & ⋯ & d ( {c}_{N} , {r}_{K} )\end{matrix} ] \qquad ( 10 )$$

In another embodiment, if all test cases are set as reference test cases, the distance matrix defined in step s408 will be D∈ [symbol] ^{N×N} which means all the data for the clustering optimization was obtained.

In step s410, the process 400 forms subsets of test cases. In particular, the test cases are divided into subsets or clusters of test cases. In some embodiments, each test case c. is assigned to the optimal subset of test cases or DPD model cluster by:

$$k = {arg min}_{k} d ( {c}_{n} , {r}_{k} ) \qquad ( 11 )$$

In other embodiments, the subsets of test cases may be formed by comparing the distance values for each reference test case. Based on the comparison, step s410 may identify a smallest calculated distance value and the associated reference test case. Then each test case will be assigned to a subset of test cases associated with the identified reference test case. In other words, each test case is assigned to a subset or cluster with the closest reference test case. In such embodiments, the subset or cluster of test cases may contain one or more reference test cases.

Table 3 below provides an illustrative example of the results of step s410. As mentioned above, the distance calculations for each reference test case provides a value. In this example, the distance values can be 1, 2, or 3, where 3>2>1. Each test case in Table 3 is assigned to a subset associated with the smallest calculated distance value. In table 3, test case #1 is assigned to the subset with reference test case #2. Test case #2 is assigned to the subset with reference test case #1. Then test case #N is assigned to the subset with reference test case #3.

TABLE 3
Sample Distance For Multiple Test Cases

| | | |
|---|---|---|
| Test Case #1 | Reference Test Case #1 | d(c₁, r₁) = 3 |
| | Reference Test Case #2 | d(c₁, r₂) = 1 |
| | Reference Test Case #3 | d(c₁, r₃) = 2 |
| Test Case #2 | Reference Test Case #1 | d(c₂, r₁) = 1 |
| | Reference Test Case #2 | d(c₂, r₂) = 2 |
| | Reference Test Case #3 | d(c₂, r₃) = 3 |
| . . . | . . . | . . . |
| Test Case #N | Reference Test Case #1 | d(c_{N}, r₁) = 2 |
| | Reference Test Case #2 | d(c_{N}, r₂) = 3 |
| | Reference Test Case #3 | d(c_{N}, r₃) = 1 |

In some embodiments, the test cases are used with a K-Means clustering approach. Based on the assumption of the traditional K-Means algorithm, the number of DPD models is K. In other embodiments, any other clustering approach may be used with any number of clusters.

Therefore, K subsets can be defined as follows:

$${C}_{k} = \{ {c}_{j} ∈ C , j = 1 , 2 , 3 , … {N}_{k} \} ⊆ C \qquad ( 12 )$$

where k=1, 2, . . . K, and

$$C = {⋃}_{k = 1}^{K} {C}_{k} \qquad ( 13 )$$

$${C}_{i} {⋂}_{i \neq j} {C}_{j} = ∅ \qquad ( 14 )$$

Then we can have

$${\sum }_{k = 1}^{K} {N}_{k} = N \qquad ( 15 )$$

In each subset Ck, we can also define the reference test cases

$${r}_{k} ∈ {C}_{k} \qquad ( 16 )$$

In step s412, a new reference test case is selected from each subset or cluster. In some embodiments, more than one reference test case is selected from a subset or cluster. There may be different ways of determining the reference test case. In some embodiments, the test case with the worst performance in each subset or cluster is selected as the new reference for the next iteration. This step is also different from the traditional K-Means, since the selection of reference test cases is based on optimization purposes, rather than the traditional mean value in the parameter space.

In step s414, process 400 determines if a convergence criterion is met. If the convergence criterion is met, process 400 moves to step s416. On the other hand, if the convergence criterion is not met, then process 400 returns to step s406.

The convergence criterion in step s414 may include one or more conditions. In some embodiments, if the set of reference test cases selected in the current iteration is the same as the one selected in the previous iteration, the algorithm can be considered to reach a converged condition.

In other embodiments, the convergence condition can be that some test cases are alternatively but repeatedly selected as the reference test cases in step s412. For example, in case test case A is selected in i-th iteration, test case B is selected in (i+1)th iteration, test case A is selected again in (i+2)th iteration, and test case B is selected again in (i+3)th iteration, it can be considered that the convergence condition has been satisfied because test cases A and B were alternatively and repeatedly selected as the reference test case. Here, the rationale is that the reference test case can be regarded as the corner case to some extent, and there can be several corner cases for one power amplifier, which means that it is very unlikely to converge to only one corner case.

In another embodiment, the convergence condition can be that the maximum iteration number is reached. For example, if the current iteration of process 400 is 4 and the maximum iteration number is 4, it can be concluded that the convergence condition has been met, and thus process 400 may proceed to step s416.

In step s416, process 400 outputs the optimized DPD models. The optimized DPD models include optimized DPD model parameters for each subset or cluster of test cases. The optimized DPD model parameters for a subset correspond to the reference test cases within the subset. The optimized DPD models may be used with new data received by circuit 200.

### Experimental Results

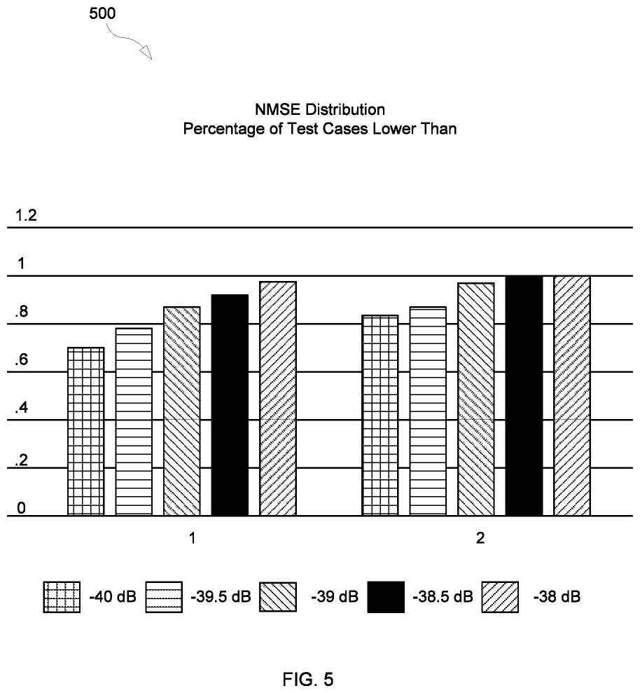

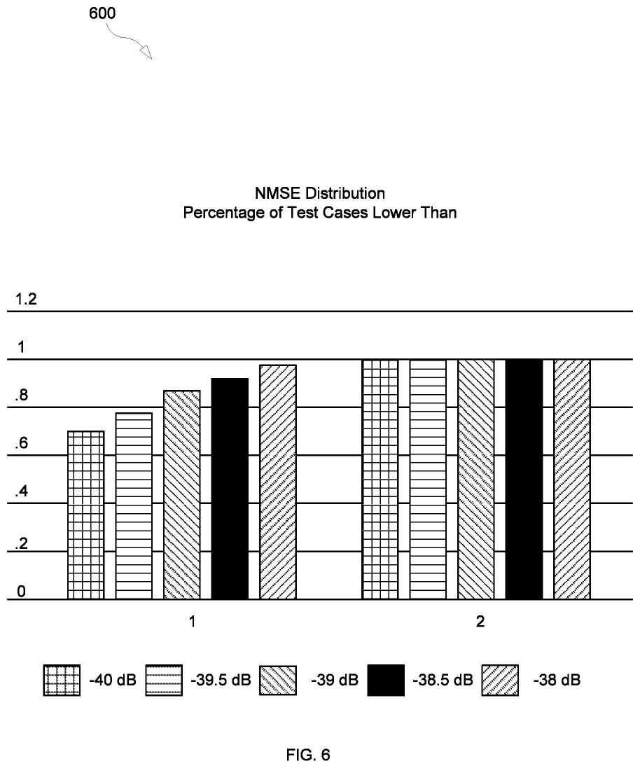

FIGS. 5 and 6 show comparing the NMSE performance of two optimization methods according to some embodiments. The graphs 500 and 600 compares the performance between prior optimization strategies and the optimization strategy described herein. The NMSE distribution results of DPD Model I and DPD Model II from a radio product are shown in FIGS. 5 and 6, respectively. In particular, in FIGS. 5 and 6, it can be seen what percentage of the test cases is lower than −40.0 dB, −39.5 dB, −39.0 dB, −38.5 dB and −38.0 dB, respectively. “1” and “2” represent the prior product optimization and the optimization described herein, respectively.

It can be concluded from FIGS. 5 and 6 that using the proposed strategy, the overall NMSE performance is improved significantly. Moreover, the worst NMSE performance is also improved for the two models, since there is no performance value lower than −38.0 dB in Model I and all performance values in Model II are higher than −40.0 dB. Here it is also noted that based on the test case assignment step, i.e., Step s410 of process 400, the boundary between Model I and Model II is also optimized. In the final results, several test cases in the legacy Model II have been assigned to the updated Model I, due to the larger performance benefit from Model I.

### Deployment for DPD Offline Optimization

The embodiments described herein may be deployed in DPD model parameter offline optimization. This deployment can be directly used in products with a product development process. By using the strategy described in at least FIG. 4 during the process of product development, the DPD model parameters can be optimized for all test cases directly based on performance. Using the processes described herein can improve DPD performance while reducing the number of DPD models. Moreover, this optimization process can be automated as shown in FIG. 4. The design cost can be saved, and the time-to-market can be shortened.

### Deployment for DPD Online Tuning

The embodiments described herein can also be deployed in radio products for online tuning a DPD during a real-time operating period. There are two alternative embodiments to handle test cases within the parameter space but not exactly defined in the original set of test cases. This kind of undefined test case is very common in real radio products. The first embodiment uses a process similar to process 400. In particular, the first embodiment runs a performance projection measurement, such as in equation (6), on the undefined test case. Then the first embodiment calculates the distance between this undefined test case and all the reference test cases. The DPD model parameters of the nearest reference case will be copied to this undefined test case. However, if there are many undefined test cases, which also distribute quite far away from the test cases in equation (5), it may be necessary to run the complete process in FIG. 4.

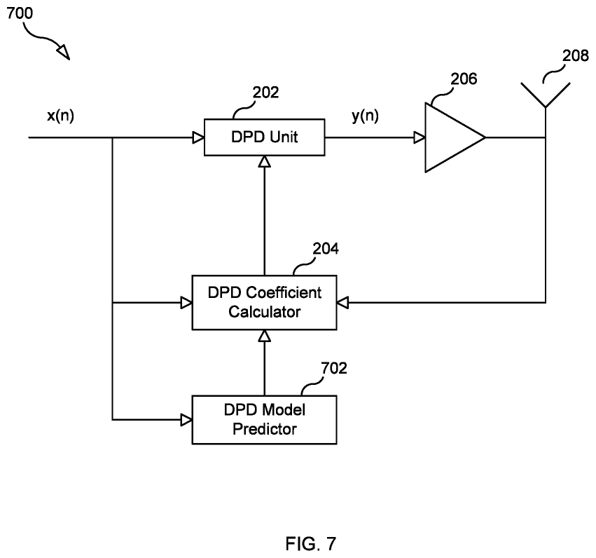

FIG. 7 shows a circuit according to some embodiments. Circuit 700 shows the second alternative embodiment using a DPD model predictor 702. The test case set in eq.(5) can be labelled based on the clustering results using process 400. Then DPD model predictor 702 can be trained using a supervised learning framework. In particular, the input of DPD model predictor 702 can include test case parameters, i.e., IBW, OBW, etc. The output can be the DPD model parameters (i.e., data delay, address delay, etc.). Different types of supervised learning algorithms can be used to train the DPD model predictor 702 (e.g., support vector machine, decision tree, neural network, etc.)

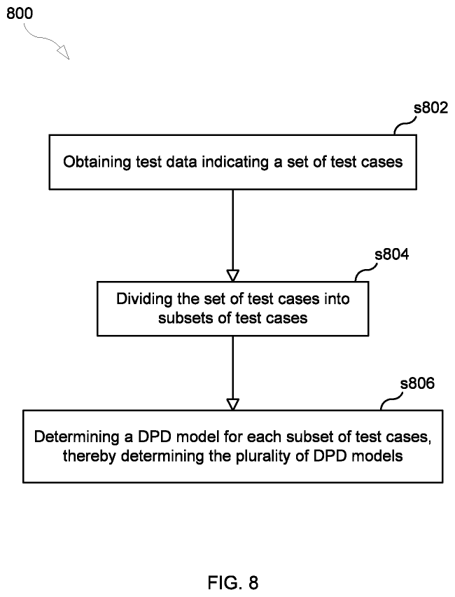

FIG. 8 shows a process 800 for determining a plurality of digital predistortion, DPD, models. The process 800 may begin with step s802. Step s802 comprises obtaining test data indicating a set of test cases. Step s804 comprises dividing the set of test cases into subsets of test cases. Step s806 comprises determining a DPD model for each subset of test cases, thereby determining the plurality of DPD models.

In some embodiments, the process comprises, for each test case, obtaining a set of performance metric, PM, values. Each PM value included in the set of PM values indicates performance measurement of the test case, which is obtained using one of the plurality of DPD models. The set of test cases is divided into the subsets of test cases based on the sets of PM values of the test cases.

In some embodiments, the process comprises selecting a set of reference test cases from the set of test cases, wherein each reference test case is associated with one or more DPD model parameters. The process comprises, for each reference test case, generating a DPD model using said one or more DPD model parameters associated with the reference test case.

In some embodiments, said one or more DPD model parameters of each reference test case include a data delay and/or an address delay.

In some embodiments, the set of PM values for each test case includes any one or more of operating band unwanted emissions margin, adjacent channel leakage ratio, and/or normalized mean squared error between a measured signal and a desired signal.

In some embodiments, dividing the set of test cases into the subsets of test cases includes for each test case, converting each PM value included in the set of PM values for the test case into a distance value using weight factors. The set of test cases is divided into the subsets of test cases based on the distance values of each test case.

In some embodiments, each reference test case is associated with a subset of test cases. Dividing the set of test cases into subsets of test cases using the calculated distance values includes, for each test case, comparing the calculated distance values of the test case to each other; based on the comparison, identifying a smallest calculated distance value from the calculated distance values of the test case; identifying a reference test case associated with the smallest calculated distance value; and assigning the test case to the subset of test cases associated with the identified reference test case.

In some embodiments, the process includes (i) selecting a first set of reference test cases from the set of test cases; (ii) determining a DPD model for each of a first set of reference test cases, thereby determining a first plurality of DPD models; (iii) obtaining PM values of each test case using the first plurality of DPD models; (iv) dividing the test cases into first subsets of test cases by assigning each test case to one of the first set of reference test cases; (v) selecting a second set of reference test cases, wherein at least one test case from each of the first subsets of test cases is selected as part of the second set of reference test cases; and (vi) determining whether a convergence criteria is satisfied.

In some embodiments, as a result of determining that the convergence criteria is not satisfied, repeating steps (ii)-(vi).

In some embodiments, the steps (ii)-(vi) are performed through N iterations, where N is a positive integer, and the convergence criteria includes any one or more of: the second set of the reference test cases obtained in the Nth iteration and the second set of reference test cases obtained in the (N−1)th iteration are the same; the second set of the reference tests cases obtained in the last M iterations is one of convergence sets of reference test cases; and/or N is greater than or equal to an iteration threshold.

In some embodiments, obtaining the test data indicating the set of test cases comprises sampling one or more test parameters to obtain the set of test cases, and the one or more test parameters include instantaneous bandwidth, occupied bandwidth, and/or weighted mean frequency.

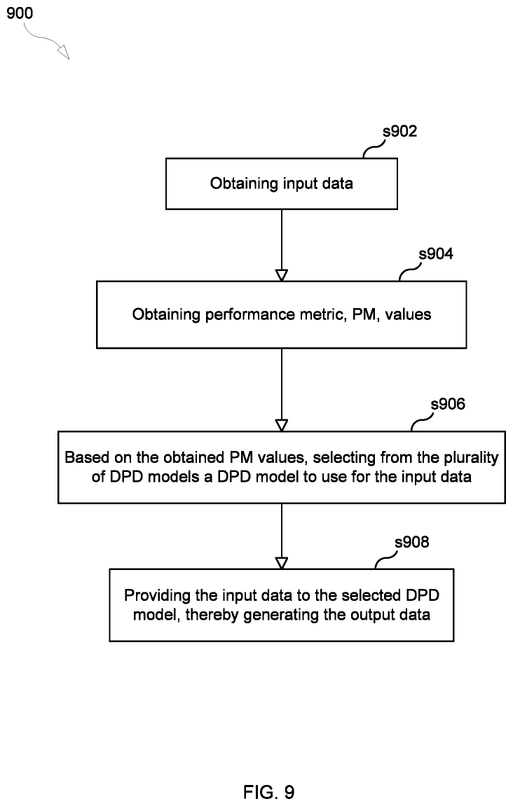

FIG. 9 shows a process 900 for generating output data using a plurality of digital predistortion, DPD, models. The process 900 may begin with step s902. Step s902 includes obtaining input data. Step s904 includes obtaining performance metric, PM, values wherein each PM value included in the PM values indicates performance measurement of the input data, which is obtained using one of the plurality of DPD models. Step s906 includes, based on the obtained PM values, selecting from the plurality of DPD models a DPD model to use for the input data. Step s908 includes providing the input data to the selected DPD model, thereby generating the output data.

In some embodiments, the process includes converting the PM values into distance values using weight factors, wherein a DPD model is selected from the plurality of DPD models using the distance values.

In some embodiments, selecting from the plurality of DPD models the DPD model to use for the input data comprises: comparing the distance values; based on the comparison, identifying a smallest distance value among the compared distance values; and assigning the input data to the DPD model associated with the smallest distance value.

In some embodiments, the PM values include: operating band unwanted emissions margin; adjacent channel leakage ratio; and/or normalized mean squared error.

In some embodiments, the input data includes parameters comprising instantaneous bandwidth and occupied bandwidth.

In some embodiments, the process includes obtaining a reformulation condition; determining whether the reformulation condition is met; as a result of determining that the reformulation condition is met, reformulating the plurality of DPD models.

In some embodiments, the reformulation condition comprises one or more of the obtained PM values is less than a performance threshold.

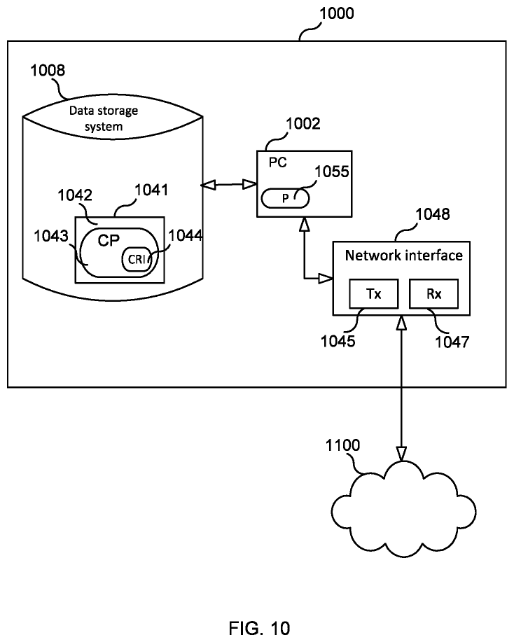

FIG. 10 is a block diagram of an apparatus (e.g., base station 104) according to some embodiments. Apparatus 1000 may perform any of the methods or processes described above. As shown in FIG. 10, the apparatus 1000 may comprise: processing circuitry (PC) 1002, which may include one or more processors (P) 1055 (e.g., a general purpose microprocessor and/or one or more other processors, such as an application specific integrated circuit (ASIC), field-programmable gate arrays (FPGAs), and the like), which processors may be co-located in a single housing or in a single data center or may be geographically distributed (i.e., the network node may be a distributed computing apparatus); at least one network interface 1048 comprising a transmitter (Tx) 1045 and a receiver (Rx) 1047 for enabling the network node to transmit data to and receive data from other nodes connected to a network 1100 (e.g., an Internet Protocol (IP) network) to which network interface 1048 is connected (directly or indirectly) (e.g., network interface 1048 may be wirelessly connected to the network 1100, in which case network interface 1048 is connected to an antenna arrangement); and a storage unit (a.k.a., “data storage system”) 1008, which may include one or more non-volatile storage devices and/or one or more volatile storage devices. In embodiments where PC 1002 includes a programmable processor, a computer program product (CPP) 1041 may be provided. CPP 1041 includes a computer readable medium (CRM) 1042 storing a computer program (CP) 1043 comprising computer readable instructions (CRI) 1044. CRM 1042 may be a non-transitory computer readable medium, such as, magnetic media (e.g., a hard disk), optical media, memory devices (e.g., random access memory, flash memory), and the like. In some embodiments, the CRI 1044 of computer program 1043 is configured such that when executed by PC 1002, the CRI causes the network node to perform steps described herein (e.g., steps described herein with reference to one or more of the flow charts). In other embodiments, the base station 104 may be configured to perform steps described herein without the need for code. That is, for example, PC 1002 may consist merely of one or more ASICs. Hence, the features of the embodiments described herein may be implemented in hardware and/or software.

While various embodiments of the present disclosure are described herein, it should be understood that they have been presented by way of example only, and not limitation. Thus, the breadth and scope of the present disclosure should not be limited by any of the above-described exemplary embodiments. Generally, all terms used herein are to be interpreted according to their ordinary meaning in the relevant technical field, unless a different meaning is clearly given and/or is implied from the context in which it is used. All references to a/an/the element, apparatus, component, means, step, etc. are to be interpreted openly as referring to at least one instance of the element, apparatus, component, means, step, etc., unless explicitly stated otherwise. Any combination of the above-described elements in all possible variations thereof is encompassed by the disclosure unless otherwise indicated herein or otherwise clearly contradicted by context.

Additionally, while the processes described above and illustrated in the drawings are shown as a sequence of steps, this was done solely for the sake of illustration. Accordingly, it is contemplated that some steps may be added, some steps may be omitted, the order of the steps may be re-arranged, and some steps may be performed in parallel. That is, the steps of any methods disclosed herein do not have to be performed in the exact order disclosed, unless a step is explicitly described as following or preceding another step and/or where it is implicit that a step must follow or precede another step.

1. A method for determining a plurality of digital predistortion (DPD) models, the method comprising:
obtaining test data indicating a set of test cases;
dividing the set of test cases into subsets of test cases; and
determining a DPD model for each subset of test cases, thereby determining the plurality of DPD models.

2. The method of claim 1, comprising:
for each test case, obtaining a set of performance metric (PM) values, wherein
each PM value included in the set of PM values indicates performance measurement of the test case, which is obtained using one of the plurality of DPD models, and
the set of test cases is divided into the subsets of test cases based on the sets of PM values of the test cases.

3. The method of claim 2, comprising:
selecting a set of reference test cases from the set of test cases, wherein each reference test case is associated with one or more DPD model parameters; and
for each reference test case, generating a DPD model using said one or more DPD model parameters associated with the reference test case.

4. The method of claim 3, wherein said one or more DPD model parameters of each reference test case include:
a data delay; and/or
an address delay.

5. The method of claim 2, wherein the set of PM values for each test case includes any one or more of:
operating band unwanted emissions margin;
adjacent channel leakage ratio; and/or
normalized mean squared error between a measured signal and a desired signal.

6. The method of claim 2, wherein dividing the set of test cases into the subsets of test cases comprises:
for each test case, converting each PM value included in the set of PM values for the test case into a distance value using weight factors, wherein
the set of test cases is divided into the subsets of test cases based on the distance values of each test case.

7. The method of claim 6, wherein
each reference test case is associated with a subset of test cases; and
dividing the set of test cases into subsets of test cases using the calculated distance values comprises:
for each test case,
comparing the calculated distance values of the test case to each other;
based on the comparison, identifying a smallest calculated distance value from the calculated distance values of the test case;
identifying a reference test case associated with the smallest calculated distance value; and
assigning the test case to the subset of test cases associated with the identified reference test case.

8. The method of claim 3, comprising:
(i) selecting a first set of reference test cases from the set of test cases;
(ii) determining a DPD model for each of a first set of reference test cases, thereby determining a first plurality of DPD models;
(iii) obtaining PM values of each test case using the first plurality of DPD models;
(iv) dividing the test cases into first subsets of test cases by assigning each test case to one of the first set of reference test cases;
(v) selecting a second set of reference test cases, wherein at least one test case from each of the first subsets of test cases is selected as part of the second set of reference test cases; and
(vi) determining whether a convergence criteria is satisfied.

9. The method of claim 8, comprising:
as a result of determining that the convergence criteria is not satisfied, repeating steps (ii)-(vi).

10. The method of claim 8, wherein
the steps (ii)-(vi) are performed through N iterations, where N is a positive integer, and
the convergence criteria includes any one or more of:
the second set of the reference test cases obtained in the Nth iteration and the second set of reference test cases obtained in the (N−1)th iteration are the same;
the second set of the reference tests cases obtained in the last M iterations is one of convergence sets of reference test cases; and/or
N is greater than or equal to an iteration threshold.

11. The method of claim 1, wherein
obtaining the test data indicating the set of test cases comprises sampling one or more test parameters to obtain the set of test cases, and
the one or more test parameters include instantaneous bandwidth, occupied bandwidth, and/or weighted mean frequency.

12. A method for generating output data using a plurality of digital predistortion (DPD) models, the method comprising:
obtaining input data;
obtaining performance metric (PM) values wherein each PM value included in the PM values indicates performance measurement of the input data, which is obtained using one of the plurality of DPD models;
based on the obtained PM values, selecting from the plurality of DPD models a DPD model to use for the input data; and
providing the input data to the selected DPD model, thereby generating the output data.

13. The method of claim 12, comprising:
converting the PM values into distance values using weight factors, wherein
a DPD model is selected from the plurality of DPD models using the distance values.

14. The method of claim 13, wherein selecting from the plurality of DPD models the DPD model to use for the input data comprises:
comparing the distance values;
based on the comparison, identifying a smallest distance value among the compared distance values; and
assigning the input data to the DPD model associated with the smallest distance value.

15. The method of claim 12, where the PM values include:
operating band unwanted emissions margin;
adjacent channel leakage ratio; and/or
normalized mean squared error.

16. The method of claim 12, wherein the input data includes parameters comprising instantaneous bandwidth and occupied bandwidth.

17. The method of claim 12, comprising:
obtaining a reformulation condition;
determining whether the reformulation condition is met; and
as a result of determining that the reformulation condition is met, reformulating the plurality of DPD models.

18. The method of claim 17, wherein the reformulation condition comprises:
one or more of the obtained PM values is less than a performance threshold.

19-23. (canceled)

24. An apparatus comprising:
a processing circuitry; and
a memory, said memory containing instructions executable by said processing circuitry, whereby the apparatus is operative to perform a method for determining a plurality of digital predistortion (DPD) models, the method comprising:
obtaining test data indicating a set of test cases;
dividing the set of test cases into subsets of test cases; and
determining a DPD model for each subset of test cases, thereby determining the plurality of DPD models.

25. An apparatus comprising:
a processing circuitry; and
a memory, said memory containing instructions executable by said processing circuitry, whereby the apparatus is operative to perform a method for generating output data using a plurality of digital predistortion (DPD) models, the method comprising:
obtaining input data;
obtaining performance metric (PM) values wherein each PM value included in the PM values indicates performance measurement of the input data, which is obtained using one of the plurality of DPD models;
based on the obtained PM values, selecting from the plurality of DPD models a DPD model to use for the input data; and
providing the input data to the selected DPD model, thereby generating the output data.
